(19) United States
(12) Patent Application Publication
(10) Pub. No.: US 2012/0161801 A1
(43) Pub. Date: Jun. 28, 2012

(54) SOLAR PHOTOVOLTAIC POWER GENERATION MODULE AND INSPECTING METHOD

(76) Inventor: Hiroshi Hasegawa, Kanagawa (JP)

(21) Appl. No.: 13/329,690

(22) Filed: Dec. 19, 2011

(30) Foreign Application Priority Data
Dec. 27, 2010 (JP) 2010-291082

(51) Int. Cl. G01R 31/26; H01L 31/042

(52) U.S. Cl. 324/750.01; 136/244

(57) ABSTRACT

A solar photovoltaic power generation module includes: plural cells connected in series with one another, and generating electric powers in correspondence to lights received; and plural bypass portions bypassing the plural cells, respectively, in accordance with an operation made from an outside.

### BACKGROUND

The present disclosure relates to a solar photovoltaic power generation module and an inspecting method of inspecting the same. More specifically, the disclosure relates to a solar photovoltaic power generation module and an inspecting method of inspecting the same which can more efficiently suppress reduction of power generation characteristics.

In general, solar photovoltaic power generation equipment includes a solar photovoltaic power generation module in which plural cells (solar cell elements) each receiving a solar light and generating an electric power are connected to one another.

FIGS. 1A to 1C are views each showing an example of a structure of a general cell. FIG. 1A is a top plan view of a cell 10, FIG. 1B is a front view of the cell 10, and FIG. 1C is a side elevational view of the cell 10 in a state in which wirings are connected to the cell 10.

As shown in FIGS. 1A and 1B, in the cell 10, two plus electrodes 11-1 and 11-2 are provided on a surface of the cell 10, and two minus electrodes 12-1 and 12-2 are provided on a back surface of the cell 10. It is noted that hereinafter, when there is no need for distinguishing the plus electrodes 11-1 and 11-2 from each other, each of the plus electrodes 11-1 and 11-2 will be suitably referred to as the plus electrode 11, and when there is no need for distinguishing the minus electrodes 12-1 and 12-2 from each other, each of the minus electrodes 12-1 and 12-2 will be suitably referred to as the minus electrode 12.

The plus electrode 11 of the cell 10 is connected to the minus electrode 12 (not shown) of another cell 10 through a wiring 13-1, and the minus electrode 12 of the cell 10 is connected to the plus electrode 11 (not shown) of another cell 10 through a wiring 13-2.

In general, an electromotive force of the cell 10 is about 0.5 V. For this reason, it is difficult to convert the electromotive force of about 0.5 V into a commercial utility voltage. In order to cope with this situation, the solar photovoltaic power generation module adopts a configuration that plural cells 10 are electrically connected in series with one another, thereby making it possible to output an electric power with which the voltage is boosted up to about 180 to about 360 V which is efficiently converted into the commercial utility voltage. Therefore, normally, several hundreds of cells 10 are connected in series with one another to configure a solar photovoltaic power generation module so that such a high voltage can be obtained.

Here, connecting several hundreds of cells 10 in series with one another means that when even one defective cell 10 of these cells 10 is generated, a current is cut off by the defective cell 10, and thus it becomes difficult to output electric powers generated from other cells 10. For this reason, hereinafter, a bypass diode is provided every solar photovoltaic power generation module configured by connecting 20 to 100 cells 10 in series with one another, whereby the solar photovoltaic power generation module having the cell 10 having the defect caused therein is bypassed.

FIG. 2 is a view showing an example of a configuration of an existing solar photovoltaic power generation module.

A solar photovoltaic power generation module 21 shown in FIG. 2 includes 20 cells 10-1 to 10-20, and a bypass diode 22.

In the solar photovoltaic power generation module 21, a plus electrode of the cell 10-1 is connected to a cathode electrode of the bypass diode 22, a minus electrode of the cell 10-1 is connected to a plus electrode of the cell 10-2, and a minus electrode of the cell 10-2 is connected to a plus electrode of the cell 10-3. Likewise, the series combination is carried out up to the cell 10-20, and a minus electrode of the cell 10-20 is connected to an anode electrode of the bypass diode 22.

For example, when a solar light is blocked by a cloud, a building or the like to generate a shadow in part of the solar photovoltaic power generation module 21, the outputs from the cells 10-1 to 10-20 connected in series with each other are reduced because of the influence of the shadow. At this time, the solar photovoltaic power generation module 21 is bypassed by the bypass diode 22, and thus only the output from the solar photovoltaic power generation module 21 is reduced. As a result, it is possible to prevent the output from being largely reduced in terms of the entire solar photovoltaic power generation equipment.

In addition, for example, Japanese Patent Laid-Open No. 2000-174308 discloses a solar photovoltaic power generation module in which a Metal Oxide Semiconductor Field Effect Transistor (MOS-FET) is used as a section for bypassing a cell not generating an electric power due to a poor solar irradiation.

### SUMMARY

As described above, in the existing solar photovoltaic power generation equipment, the bypass diode is provided every solar photovoltaic power generation module. When the defect is caused in part of cells, the bypass is carried out in units of the solar photovoltaic power generation module having the detective cell. For this reason, the electric powers generated from the cells other than the defective cell in the solar photovoltaic power generation module concerned are also not outputted, and thus the efficiency is poor.

In general, plural cells composing the solar photovoltaic power generation module have a sealed structure. Thus, it is difficult to avoid the reduction of the output in terms of the entire solar photovoltaic power generation module by bypassing only the detective cell from the outside after completion of the construction.

The present disclosure has been made in order to solve the problems described above, and it is therefore desirable to provide a solar photovoltaic power generation module, and an inspecting method for inspecting the same which are capable of more efficiently suppressing reduction of power generation characteristics.

According to an embodiment of the present disclosure, there is provided a solar photovoltaic power generation module including: plural cells connected in series with one another, and generating electric powers in correspondence to lights received; and plural bypass portions bypassing the plural cells, respectively, in accordance with an operation made from an outside.

In the embodiment of the present disclosure, the plural cells connected in series with one another, and generating the electric powers in correspondence to the lights received are bypassed by the plural bypass portions which carry out the bypass in accordance with the operation made from the outside.

According to another embodiment of the present disclosure, there is provided an inspecting method for a solar photovoltaic power generation module automatically inspecting system including a solar photovoltaic power generation module having plural cells connected in series with one another, and generating electric powers in correspondence to lights received, and plural bypass portions bypassing the plural cells, correspondingly, in accordance with an operation made from an outside, a voltage measuring portion measuring a voltage of an electric power outputted from the solar photovoltaic power generation module, a current measuring portion measuring a current of the electric power outputted from the solar photovoltaic power generation module, and a control portion monitoring the voltage and the current, and controlling bypass made by the plural bypass portions, the inspecting method including: successively selecting the plural cells each becoming an object of an inspection; bypassing the cell selected by the bypass portion corresponding to the cell selected; and determining whether or not the cell bypassed is normal based on the voltage and the current, and recording the cell which is determined not to be normal.

As set forth hereinabove, according to the present disclosure, the reduction of the power generation characteristics can be more efficiently suppressed.

### BRIEF DESCRIPTION OF THE DRAWINGS

FIGS. 1A, 1B, and 1C are respectively a top plan view, a front view, and a side elevational view each showing an example of a structure of a general cell;

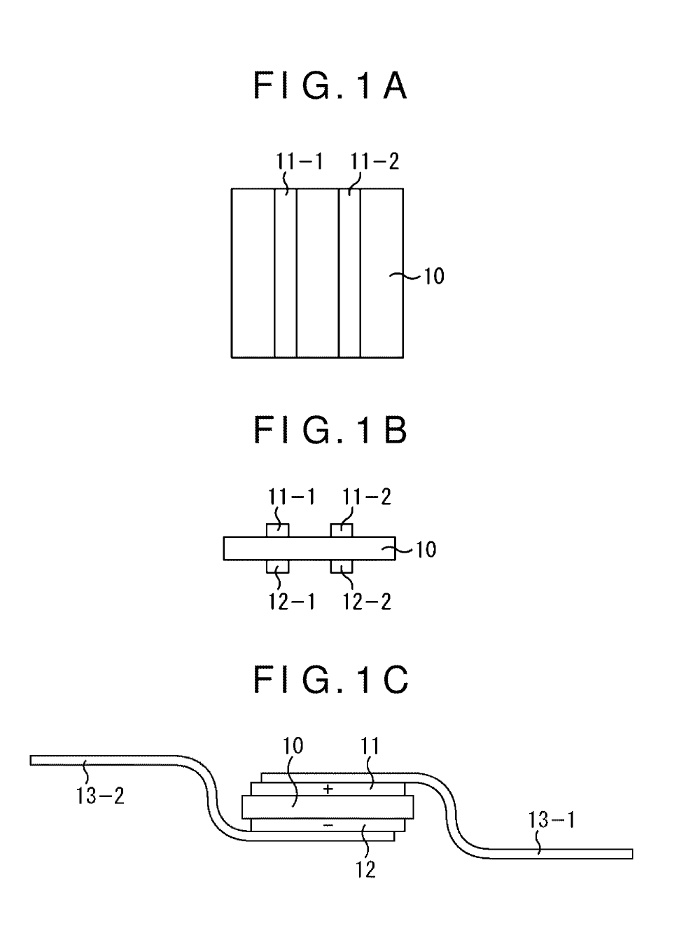

FIG. 2 is a view showing an example of a configuration of an existing solar photovoltaic power generation module;

FIG. 3 is a view showing a configuration of a solar photovoltaic power generation module according to a first embodiment of the present disclosure;

FIGS. 4A and 4B are respectively a view showing a construction of a bypass switch shown in FIG. 3 in an open state, and a view showing the construction of the bypass switch shown in FIG. 3 in a connection state;

FIGS. 5A and 5B are respectively a view showing a construction of a bypass switch of a change of the bypass switch shown in FIGS. 4A and 4B in an open state, and a view showing the construction of the bypass switch of the change of the bypass switch shown in FIGS. 4A and 4B in a connection state;

FIG. 6 is a view showing a configuration of a solar photovoltaic power generation module according to a second embodiment of the present disclosure;

FIG. 7 is a view showing a configuration of a solar photovoltaic power generation module according to a third embodiment of the present disclosure;

FIGS. 8A and 8B are respectively a view of a front surface of the solar photovoltaic power generation module shown in FIG. 3, and a view of a back surface of the solar photovoltaic power generation module shown in FIG. 3;

FIG. 9 is a circuit diagram showing wirings in a drive circuit for driving the bypass switches;

FIG. 10 is a view showing a configuration of a solar photovoltaic power generation module according to a fourth embodiment of the present disclosure;

FIG. 11 is a block diagram showing an example of a configuration of an automatically inspecting system for automatically inspecting a solar photovoltaic power generation module;

FIG. 12 is a flow chart explaining processing for inspecting the solar photovoltaic power generation module; and

FIG. 13 is a flow chart explaining processing for optimally controlling the solar photovoltaic power generation module.

### DETAILED DESCRIPTION OF THE PREFERRED EMBODIMENTS

Embodiments of the present disclosure will be described in detail hereinafter with reference to the accompanying drawings.

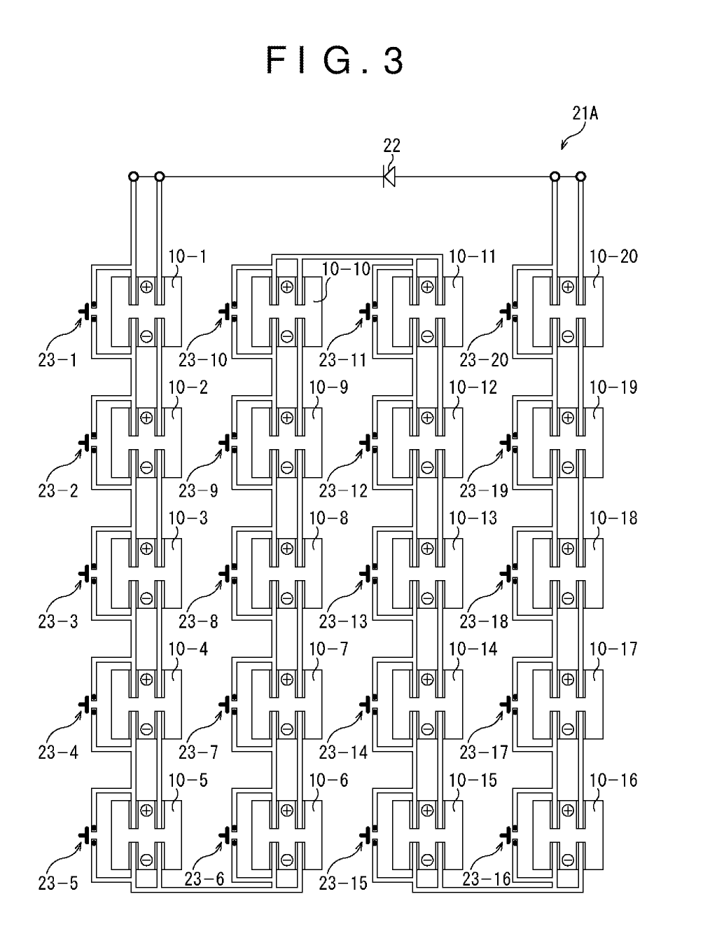

FIG. 3 is a view showing a configuration of a solar photovoltaic power generation module according to a first embodiment of the present disclosure.

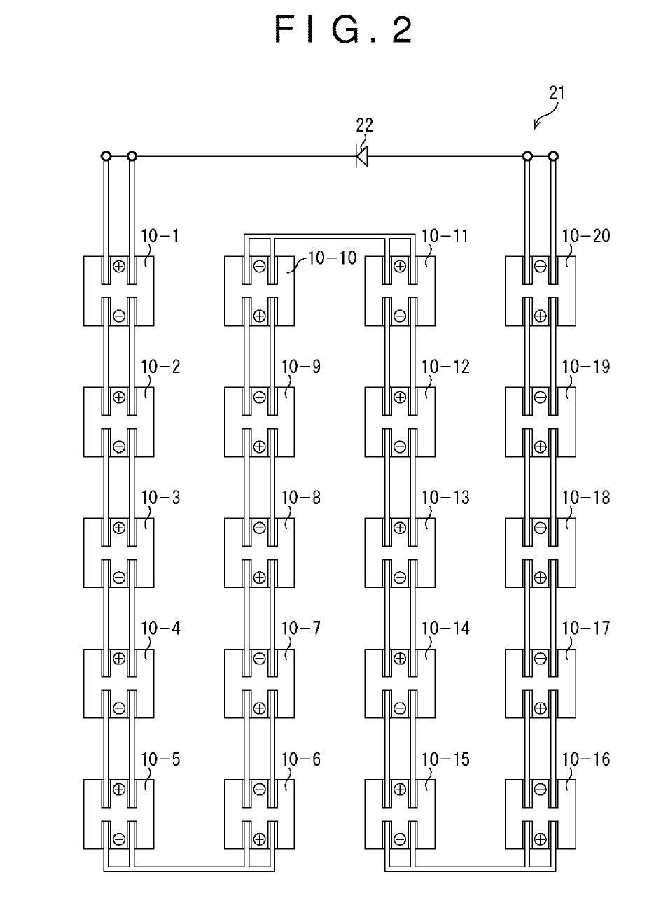

As shown in FIG. 3, the solar photovoltaic power generation module 21A has the same configuration as that of the solar photovoltaic power generation module 21 shown in FIG. 2 in that 20 cells 10-1 to 10-20 are connected in series with one another, and the bypass diode 22 is connected between both ends of the solar photovoltaic power generation module 21A. However, the solar photovoltaic power generation module 21A has a different configuration from that of the solar photovoltaic power generation module 21 in that the solar photovoltaic power generation module 21A includes bypass switches 23-1 to 23-20 corresponding to the cells 10-1 to 10-20, correspondingly.

That is to say, in the solar photovoltaic power generation module 21A, the bypass switch 23-1 is openably and closably disposed between the plus electrode and the minus electrode of the cell 10-1. In addition, the bypass switch 23-2 is openably and closably disposed between the plus electrode and the minus electrode of the cell 10-2. Likewise, the bypass switch 23-20 is openably and closably disposed between the plus electrode and the minus electrode of the cell 10-20.

The cells 10-1 to 10-20 and the bypass switches 23-1 to 23-20 are all enclosed within a chassis of the solar photovoltaic power generation module 21A. Also, each of the bypass switches 23-1 to 23-20 is configured in such a way that contact points thereof are connected to each other by application of a magnetic force from the outside of the chassis. For example, in the solar photovoltaic power generation module 21A, a user carries out a manipulation for making a magnet come close to each of the bypass switches 23-1 to 23-20 from the outside, which results in that the plus electrodes and the minus electrodes of the cells 10-1 to 10-20 are individually short-circuited. Here, when there is no need for distinguishing the bypass switches 23-1 to 23-20 from one another, hereinafter, each of the bypass switches 23-1 to 23-20 will be suitably referred to as the bypass switch 23. By the same token, each of the cells 10-1 to 10-20 will be suitably referred to as the cell 10.

Thus, when the defect is caused in any of the cells 10 of the solar photovoltaic power generation module 21A, the user makes the magnet come close to the bypass switch 23 corresponding to the defective cell 10, thereby making it possible to bypass the defective cell 10. As a result, the defective cell 10 is bypassed, whereby the electric powers generated from other cells 10 can be outputted from the solar photovoltaic power generation module 21A, and it is possible to prevent the output from the solar photovoltaic power generation module 21A as a whole from being reduced. That is to say, it is possible to suppress the reduction of the power generation characteristics of the solar photovoltaic power generation module 21A.

Next, a description will be given with respect to a construction of the bypass switch 23.

A general magnetic proximity switch may be used as the bypass switch 23. However, when it is taken into consideration that the bypass switch 23 is disposed inside the solar photovoltaic power generation module 21A, preferably, a height of the bypass switch 23 is made equal to that of the cell 10 as much as possible. That is to say, a low height type bypass switch 23 having a height of several millimeters or less is preferable as the bypass switch 23. On the other hand, since the degree of freedom for an area of the bypass switch 23 is large, a contact point made of a magnetic material (such as iron or nickel) attracted by the magnet made to come close to the contact point can be made large in size. Therefore, the magnetic material is made large in size, which results in that the bypass switch 23 can operate without using a strong magnet.

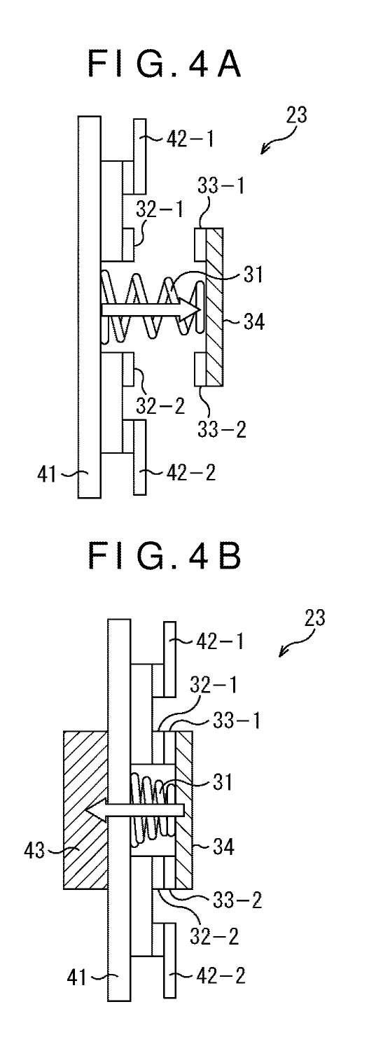

FIGS. 4A and 4B are views each showing a construction of the bypass switch 23. FIG. 4A shows the bypass switch 23 in an open state, and FIG. 4B shows the bypass switch 23 in a connection state.

As shown in FIGS. 4A and 4B, the bypass switch 23 includes a coil spring 31, fixed contact portions 32-1 and 32-2, movable contact portions 33-1 and 33-2, and a magnetic member 34.

In addition, the bypass switch 23 is fixed to an internal wall surface of the back sheet 41 which is disposed on a back surface side of the solar photovoltaic power generation module 21A as a chassis for enclosing the cell 10. That is to say, both of the fixed contact portions 32-1 and 32-2 are fixed to the back sheet 41, and one end of the coil spring 31 is fixed between the fixed contact portions 32-1 and 32-2. In addition, the magnetic member 34 is mounted to the other end of the coil spring 31, and the movable contact portions 33-1 and 33-2 are fixed to the vicinities of the both ends of the magnetic member 34, correspondingly. Also, the movable contact portions 33-1 and 33-2 are disposed in the vicinities of the both ends of the magnetic member 34 so as to face the fixed contact portions 32-1 and 32-2, respectively.

A wiring 42-1 connected to the plus terminal of the cell 10, for example, is electrically connected to the fixed contact portions 32-1. Also, a wiring 42-2 connected to the minus terminal of the cell 10, for example, is electrically connected to the fixed contact portions 32-2. The magnetic material 34 is made of a material such as iron which responses to the magnetic force, and the back sheet 41 is made of a material such as a resin or a glass which does not block the magnetic force. The bypass switch 23 is constructed in such a manner.

In a normal state (in a state in which no manipulation made from the outside is carried out), as shown in FIG. 4A, a state in which the fixed contact portions 32-1 and 32-2, and the movable contact portions 33-1 and 33-2 do not contact each other, respectively, is maintained by an urging force of the coil spring 31. As a result, the bypass switch 23 is held in the open state.

On the other hand, as shown in FIG. 4B, when the user makes the magnet 43 come close to the external wall surface, of the back sheet 41, in a portion in which the bypass switch 23 is disposed from the outside of the solar photovoltaic power generation module 21A, the magnetic member 34 is attracted to the magnet 43 by the magnetic force of the magnet 43. As a result, a state in which the fixed contact portions 32-1 and 32-2, and the movable contact portions 33-1 and 33-2 contact each other, respectively, is obtained, and thus a current can be caused to flow through the magnetic member 34. As a result, the bypass switch 23 is held in the connection state.

The magnet 43 is made to come close to the external wall surface of the back sheet 41 to hold the bypass switch 23 in the connection state, thereby making it possible to short-circuit the plus terminal and the minus terminal of the cell 10. As a result, for example, the bypass switch 23 corresponding to the cell 10 having the defect caused therein is held in the connection state, whereby it is possible to prevent no electric power from the entire solar photovoltaic power generation module 21A from being outputted by bypassing the defective cell 10.

That is to say, in the solar photovoltaic power generation module 21A, even after completion of the construction in the state in which the bypass switch 23 is enclosed within the chassis, the manipulation for the bypass switch 23 can be carried out from the outside, the cell 10 having the defect caused therein can be bypassed, and the maintenance can be carried out. That is to say, since the solar photovoltaic power generation module is normally impregnated with a resin or the like, the supplement in units of the cell is difficult to carry out after completion, and thus it is necessary to replace the entire solar photovoltaic power generation module with another one. On the other hand, in the solar photovoltaic power generation module 21A, the maintenance is carried out every cell 10, thereby avoiding that the entire solar photovoltaic power generation module 21A is replaced with another one. Therefore, even when the solar photovoltaic power generation module 21A is used for the building material, the risk when the defect is caused after completion of the construction can be minimally lightened.

In addition, a simple part like the coil spring 31 is adopted as the urging section, which results in that the bypass switch 23 can be constructed in the form of a simple construction and at the low cost. It is noted that any other suitable part other than the coil spring 31 may be adopted as the urging section.

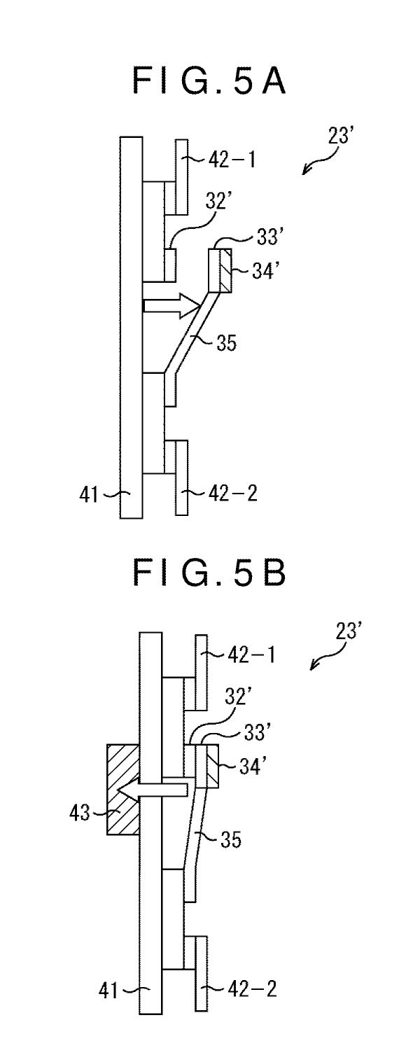

That is to say, FIGS. 5A and 5B show a change of the bypass switch 23. FIG. 5A shows a bypass switch 23′ in an open state, and FIG. 5B shows the bypass switch 23′ in a connection state.

As shown in FIGS. 5A and 5B, the bypass switch 23′ includes a plate spring 35, a fixed contact portion 32′, a movable contact portion 33′, and a magnetic member 34′. That is to say, in the bypass switch 23′, the plate spring 35 is used instead of using the coil spring 31 of the bypass switch 23 shown in FIGS. 4A and 4B.

The wiring 42-1 connected to the plus terminal of the cell 10, for example, is electrically connected to the fixed contact portion 32′. Also, the wiring 42-2 connected to the minus terminal of the cell 10, for example, is electrically connected to one end of the plate spring 35. In addition, both of the movable contact portion 33′ and the magnetic member 34′ are mounted the other end of the plate spring 35.

In the bypass switch 23′, in the normal state, as shown in FIG. 5A, a state in which the fixed contact portion 32′, and the movable contact portion 33′ do not contact each other is maintained by an urging force of the plate spring 35. As a result, the bypass switch 23′ is held in the open state. Also, as shown in FIG. 5B, when the user makes the magnet 43 come close to the bypass switch 23′, the magnetic member 34′ is attracted to the magnet 43 by the magnetic force of the magnet 43. As a result, a state in which the fixed contact portion 32′ and the movable contact portion 33′ come in contact with each other is obtained, thereby making it possible to cause the current to flow through the plate spring 35. As a result, the bypass switch 23′ is held in the connection state.

Note that, in FIGS. 4A and 4B and FIGS. 5A and 5B, there is adopted the construction such that each of the bypass switches 23 and 23′ is manipulated from the back surface side of the solar photovoltaic power generation module 21A through the back sheet 41. Alternatively, however, it is also possible to adopt a construction such that the bypass switch 23 is manipulated from the front surface of the solar photovoltaic power generation module 21A.

Here, as with the solar photovoltaic power generation module 21A shown in FIG. 3, the configuration is ideal such that the bypass switches 23-1 to 23-20 are provided for all of the cells 10-1 to 10-20 composing the solar photovoltaic power generation module 21A, correspondingly. However, it is preferable to simplify the configuration of the solar photovoltaic power generation module 21A from viewpoints of the complication of the internal wirings, the reduction of the manufacturing cost, the enhancement of the workability in the phase of the manufacture, and the like.

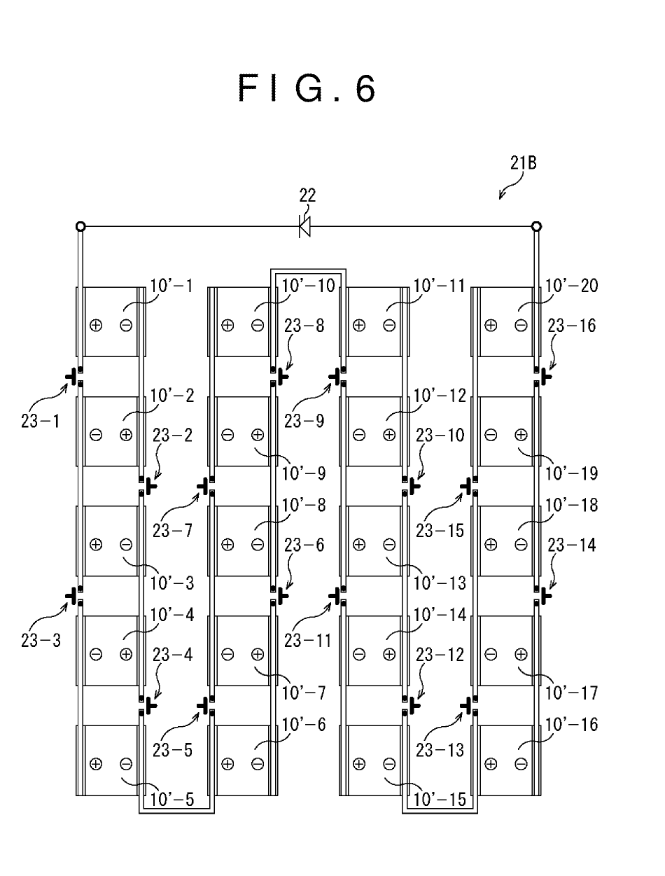

Next, FIG. 6 is a view showing a configuration of a solar photovoltaic power generation module according to a second embodiment of the present disclosure.

The solar photovoltaic power generation module 21B shown in FIG. 6 includes 20 cells 10′-1 to 10′-20 connected in series with one another, the bypass diode 22 connected between both of the ends of the solar photovoltaic power generation module 21B, and 16 bypass switches 23-1 to 23-16. In addition, the cell 10′ used in the solar photovoltaic power generation module 21B is configured in such a way that the plus electrode is disposed in the vicinity of one side surface thereof, and the minus electrode is disposed in the vicinity of the other side surface thereof.

In the solar photovoltaic power generation module 21B, the minus electrode of the cell 10′-1, and the plus electrode of the cell 10′-2 are connected to each other. Also, the bypass switch 23-1 is disposed between the plus electrode of the cell 10′-1 and the minus electrode of the cell 10′-2. In addition, the minus electrode of the cell 10′-2, and the plus electrode of the cell 10′-3 are connected to each other. Also, the bypass switch 23-2 is disposed between the plus electrode of the cell 10′-2 and the minus electrode of the cell 10′-3. Likewise, in the solar photovoltaic power generation module 21B, in the form of the connection between the plus electrode of the cell 10′ and the minus electrode of the cell 10′ adjacent thereto, the bypass switches 23 are alternately disposed.

The solar photovoltaic power generation module 21B is configured in such a way. Thus, when the defect is caused in any of the cells 10′, the bypass switch 23 on any one of the both sides of the defective cell 10′ is made in the connection state, which results in that the defective cell 10′ can be bypassed. In this case, the cell 10′, on the side of the bypass switch 23 which is made in the connection state, which is adjacent to the defective cell 10′ can also be bypassed. That is to say, in the solar photovoltaic power generation module 21B, the bypass is carried out in units of the adjacent two cells 10′. It is noted that which of the bypass switch 23 sides is made in the connection state for the cell 10′ having the defect caused therein can be arbitrarily selected.

In such a way, the solar photovoltaic power generation module 21B is configured such that the bypass switches 23 are disposed so as to be capable of being bypassed in units of the adjacent two cells 10′. As a result, the wirings can be wired more simply in the solar photovoltaic power generation module 21B than in the solar photovoltaic power generation module 21A. Also, in the solar photovoltaic power generation module 21B, the number of bypass switches 23 can be reduced from 20 to 16.

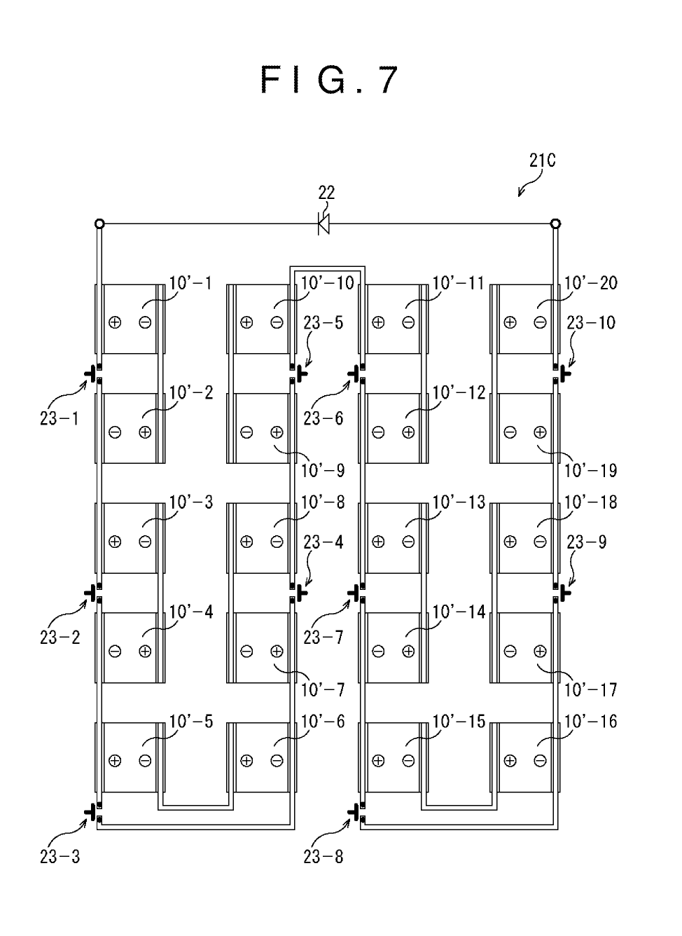

Next, FIG. 7 is a view showing a configuration of a solar photovoltaic power generation module according to a third embodiment of the present disclosure.

The solar photovoltaic power generation module 21C shown in FIG. 7 has the same configuration as that of the solar photovoltaic power generation module 21B shown in FIG. 6 in that 20 cells 10′-1 to 10′-20 are connected in series with one another and the bypass diode 22 is connected between both of the ends of the solar photovoltaic power generation module 21C. However, the solar photovoltaic power generation module 21C includes 10 bypass switches 23-1 to 23-10, and the form of the connection of the bypass switches 23-1 to 23-10 is different from that of the connection of the bypass switches 23-1 to 23-16 in the solar photovoltaic power generation module 21B shown in FIG. 6.

That is to say, in the solar photovoltaic power generation module 21C, the minus electrode of the cell 10′-1 and the plus electrode of the cell 10′-2 are connected to one another, and the bypass switch 23-1 is disposed between the plus electrode of the cell 10′-1 and the minus electrode of the cell 10′-2. In addition, the minus electrode of the cell 10′-2 and the plus electrode of the cell 10′-3 are connected to each other. Here, the plus electrode of the cell 10′-2 and the minus electrode of the cell 10′-3 are not connected to each other.

Also, in the solar photovoltaic power generation module 21C, the minus electrode of the cell 10′-3 and the plus electrode of the cell 10′-4 are connected to one another, and the bypass switch 23-2 is disposed between the plus electrode of the cell 10′-3 and the minus electrode of the cell 10′-4. Likewise, in the solar photovoltaic power generation module 21C, the bypass switch 23 is disposed every one set of cells 10′ adjacent to each other.

The solar photovoltaic power generation module 21C is configured in such a way. Thus, when the defect is caused in any of the cells 10′, the bypass switch 23 disposed between the defective cell 10′ and the cell 10′ adjacent thereto is made in the connection state, which results in that the defective cell 10′ can be bypassed. In this case, the cell 10′ which is adjacent to the defective cell 10′ can also be bypassed. That is to say, the solar photovoltaic power generation module 21C has the configuration such that when the defect is caused in a certain cell 10′, the cell 10′ which is bypassed together with the defective cell 10′ is previously determined without the overlapping of a combination of the cells 10′ which are bypassed.

In such a way, the solar photovoltaic power generation module 21C is configured such that the bypass switches 23 are disposed so as to be capable of being bypassed in units of the adjacent two cells 10′. As a result, the wirings can be wired more simply in the solar photovoltaic power generation module 21C than in the solar photovoltaic power generation module 21A. Also, in the solar photovoltaic power generation module 21C, the number of bypass switches 23 can be reduced from 20 to 10. It is noted that the setting of the cell 10′ which is bypassed can be freely designed, for example, either every one cell 10′ or plural cells 10′ (two or more cells 10′ are also possible), and thus can be used depending on the use application or the cost appropriately.

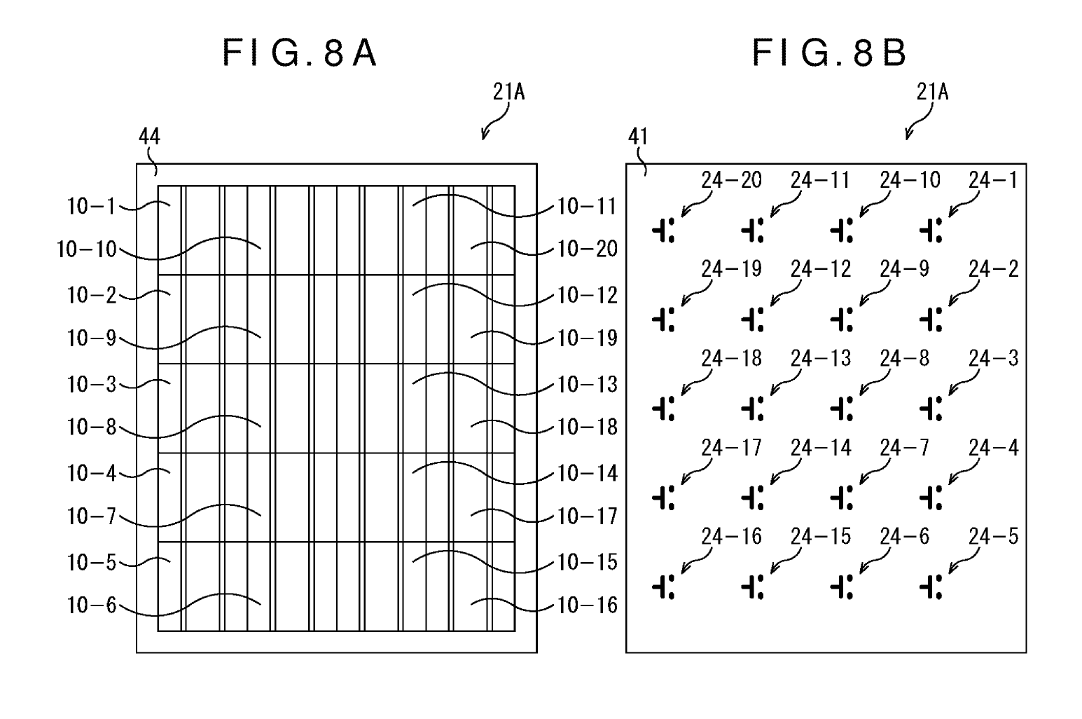

Next, a description will be given with respect to the case where the maintenance is carried out when the solar photovoltaic power generation module 21A of the first embodiment is actually used with reference to FIGS. 8A and 8B. FIG. 8A shows the front surface of the solar photovoltaic power generation module 21A, and FIG. 8B shows the back surface of the solar photovoltaic power generation module 21A.

The front surface of the solar photovoltaic power generation module 21A is covered with a front sheet 44 made of a transparent plate material such as a glass or an acrylic resin. Also, the back surface of the solar photovoltaic power generation module 21A is covered with the back sheet 41 as previously described with reference to FIGS. 4A and 4B, and FIGS. 5A and 5B. In addition, a side surface of the solar photovoltaic power generation module 21A is surrounded by a member (not shown), and the cells 10-1 to 10-20 are enclosed within the chassis of the solar photovoltaic power generation module 21A.

In addition, as shown in FIG. 3, the solar photovoltaic power generation module 21A includes the bypass switches 23-1 to 23-20 corresponding to the cells 10-1 to 10-20, respectively. Also, markings 24-1 to 24-20 are marked in portions corresponding to the bypass switches 23-1 to 23-20, respectively, disposed inside the solar photovoltaic power generation module 21A in the back sheet 41.

For example, the user makes the permanent magnet come close to the markings 24-1 to 24-20 in order while the output voltage and the output current from the solar photovoltaic power generation module 21A desired to be inspected are monitored. Also, when the user makes the permanent magnet come close to the marking 24 of the bypass switch 23 corresponding to the normal cell 10, and carries out the manipulation for bypassing the normal cell 10, both of the output voltage and the output current from the solar photovoltaic power generation module 21A are reduced in correspondence to an energy of the electric power generated by the normal cell 10 concerned. On the other hand, when the user makes the permanent magnet come close to the marking 24 of the bypass switch 23 corresponding to the cell 10 having the defect caused therein, and carries out the manipulation for bypassing the defective cell 10, the cut-off of the current by the defective cell 10 is avoided, and thus the output current from the solar photovoltaic power generation module 21A is increased.

The output current is increased in such a way, which results in that the user can readily detect that the defect is caused in the cell 10 which becomes an object of the manipulation when the output current from the solar photovoltaic power generation module 21A is increased.

Therefore, when the user detects the defective cell 10 through the inspection for the solar photovoltaic power generation module 21A, for example, the user can carry out a treatment for fixing the permanent magnet to the portion of the marking 24 corresponding to the defective cell 10 by using an adhesive agent or the like. As a result, the cell 10 having the defect caused therein can be always bypassed by the bypass switch 23 corresponding to the defective cell 10, and thus it is possible to prevent the power generation characteristics from being reduced in terms of the entire solar photovoltaic power generation module 21A. That is to say, in the solar photovoltaic power generation module 21A, only the cell 10 having the defect caused therein can be minimally bypassed, thereby maintaining the outputs from other cells. In such a way, the maintenance can be readily and reliably carried out.

In addition, the solar irradiation condition is changed due to the change in external environment of the solar photovoltaic power generation module 21A, for example, due to newly building a building near the installation place, whereby the solar light is not radiated to part of the cells 10 of the solar photovoltaic power generation module 21A on a permanent basis in some cases. Even in such cases, the user can carry out the manipulation from the outside so that the cell 10 to which the solar light is not permanently radiated is bypassed by the bypass switch 23 corresponding to the cell 10 concerned. As a result, it is possible to prevent the power generation characteristics from being reduced in terms of the entire solar photovoltaic power generation module 21A.

It is noted that, for example, when the back sheet 41 is made of a transparent resin or glass, and thus the bypass switches 23-1 to 23-20 disposed inside the solar photovoltaic power generation module 21A can be visually recognized from the outside, it is unnecessary to mark the markings 24-1 to 24-20.

Note that, the solar photovoltaic power generation module 21A shown in FIG. 3 is configured in such a way that when the magnet is made to come close to the bypass switches 23-1 to 23-20 in order from the outside, the bypass switches 23-1 to 23-20 are held in the connection state in order. However, the switching between the open and the connection of each of the bypass switches 23-1 to 23-20 may be carried out by using a magnetic coil. For example, as marked in the markings 24-1 to 24-20, in the solar photovoltaic power generation module 21A, the positions where the bypass switches 23-1 to 23-20 are disposed, respectively, are previously decided. Then, the magnetic coils are provided in portions corresponding to the bypass switches 23-1 to 23-20, respectively, and the bypass switches 23-1 to 23-20 can be electrically driven by these magnetic coils, respectively.

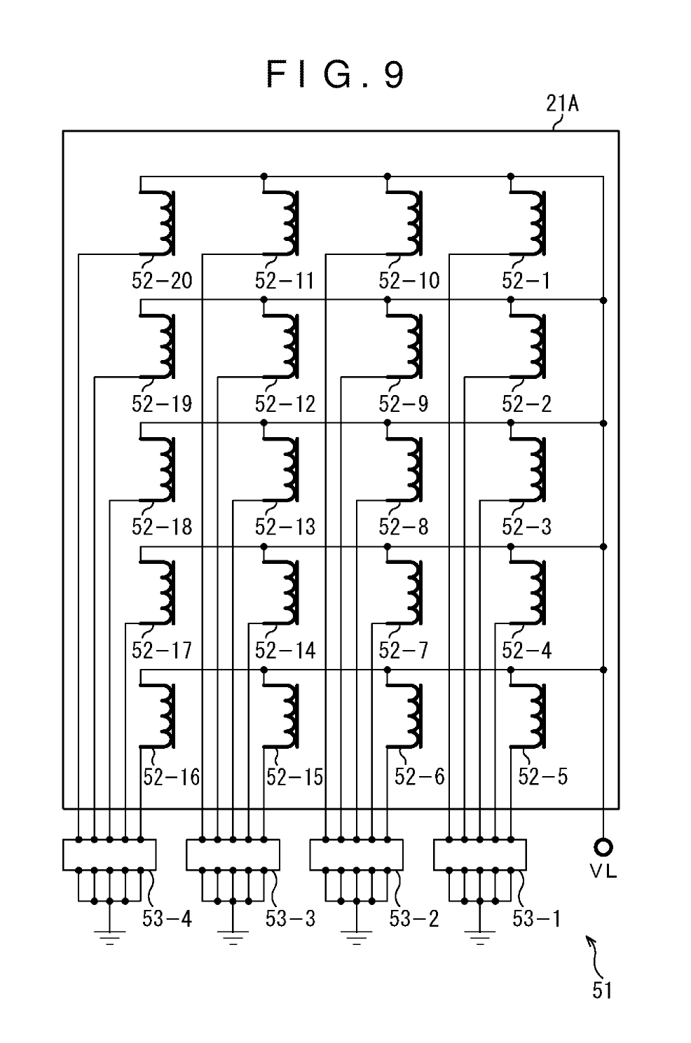

FIG. 9 is a circuit diagram showing wirings of a drive circuit for driving the bypass switches 23-1 to 23-20.

As shown in FIG. 9, the drive circuit 51 includes 20 magnetic coils 52-1 to 52-20, and four control switches 53-1 to 53-4.

The magnetic coils 52-1 to 52-20 are provided in portions corresponding to the bypass switches 23-1 to 23-20 (for example, portions of the markings 24-1 to 24-20 shown in FIG. 8B) disposed inside the solar photovoltaic power generation module 21A.

In addition, one ends of the magnetic coils 52-1 to 52-20 are connected to a power source VL, and the other ends thereof are grounded through the control switches 53-1 to 53-4. That is to say, the other ends of the magnetic coils 52-1 to 52-5 are grounded through the control switch 53-1. The other ends of the magnetic coils 52-6 to 52-10 are grounded through the control switch 53-2. The other ends of the magnetic coils 52-11 to 52-15 are grounded through the control switch 53-3. Also, the other ends of the magnetic coils 52-16 to 52-20 are grounded through the control switch 53-4.

For example, the user individually selects and grounds the magnetic coils 52-1 to 52-20 by manipulating the control switches 53-1 to 53-4, thereby making it possible to cause a current to flow through the magnetic coil 52 selected. As a result, an electromagnetic force is generated in the magnetic coil 52 selected, and thus the bypass switch 23 located in the portion in which the magnetic coil 52 selected is provided becomes a closing state. As a result, the cell 10 corresponding to the bypass switch 23 in the closing state can be bypassed.

By utilizing the drive circuit 51 in such a way, the user can freely select an arbitrary bypass switch 23, thereby opening and closing the arbitrary bypass switch 23 thus selected. Therefore, the solar photovoltaic power generation module 21A can be more readily inspected as compared with such an inspecting method as to make the magnet come close to the bypass switches 23 in order in the manner as described above.

It is noted that the magnetic coils 52-1 to 52-20 can be previously fixed to the back surface of the solar photovoltaic power generation module 21A, and in addition thereto, can adopt such a construction as to be capable of being dismounted as may be necessary. In addition, preferably, only when the solar photovoltaic power generation module 21A is inspected, the magnetic coils 52-1 to 52-20 are mounted. In this case, for example, it is possible to adopt a construction such that the magnetic coils 52-1 to 52-20 are mounted to a frame or the like with which the dispositions of the magnetic coils 52-1 to 52-20 are fixed, and the magnetic coils 52-1 to 52-20, including the whole frame, are provided on the back surface of the solar photovoltaic power generation module 21A.

Also, in addition to use of a switch like the bypass switch 23, for example, a Field Effect Transistor (FET) can be used as the bypass section for bypassing the cell 10.

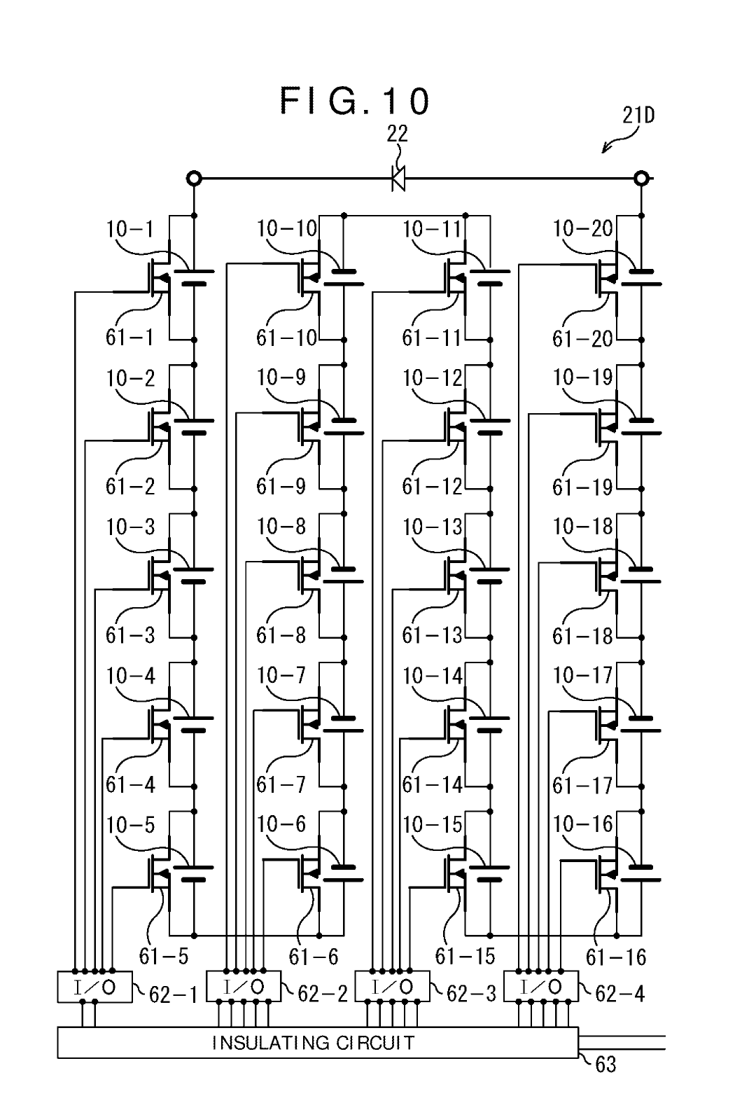

FIG. 10 is a view showing a configuration of a solar photovoltaic power generation module according to a fourth embodiment of the present disclosure. A wiring diagram of the solar photovoltaic power generation module 21D is shown in FIG. 10.

The solar photovoltaic power generation module 21D shown in FIG. 10 has the same configuration as that of the solar photovoltaic power generation module 21A shown in FIG. 3 in that the solar photovoltaic power generation module 21D includes 20 cells 10-1 to 10-20, and the bypass diode 22.

On the other hand, the solar photovoltaic power generation module 21D has the different configuration from that of the solar photovoltaic power generation module 21A in that the solar photovoltaic power generation module 21D includes 20 FETs 61-1 to 61-20, four I/O ports (I/O) 62-1 to 62-4, and an insulating circuit 63. That is to say, in the solar photovoltaic power generation module 21D, the FETs 61-1 to 61-20 are provided so as to correspond to the cells 10-1 to 10-20, respectively, instead of providing the bypass switches 23-1 to 23-20.

Source terminals of the FETs 61-1 to 61-20 are connected to the plus electrodes of the cells 10-1 to 10-20, respectively, and drain terminals of the FETs 61-1 to 61-20 are connected to the minus electrodes of the cells 10-1 to 10-20, respectively. In addition, gate terminals of the FETs 61-1 to 61-5 are connected to the insulating circuit 63 through the I/O port 62-1, and gate terminals of the FETs 61-6 to 61-10 are connected to the insulating circuit 63 through the I/O port 62-2. Also, gate terminals of the FETs 61-11 to 61-15 are connected to the insulating circuit 63 through the I/O port 62-3, and gate terminals of the FETs 61-16 to 61-20 are connected to the insulating circuit 63 through the I/O port 62-4.

For example, switch selection serial data representing that any of the FETs 61-1 to 61-20 is selected is supplied to the insulating circuit 63. The insulating circuit 63 individually insulates the FETs 61-1 to 61-20 through the I/O ports 62-1 to 62-4 in accordance with the switch selection serial data supplied thereto. As a result, the cell 10 corresponding to the FET 61 selected in accordance with the switch selection serial data is bypassed.

In such a way, in the solar photovoltaic power generation module 21D, the FETs 61-1 to 61-20 are adopted as the bypass sections of the cells 10-1 to 10-20, respectively. As a result, the FETs 61-1 to 61-20 are excellent in preservation and use for an extended period of time as compared with the case of the switches each having the mechanical contact because the FETs 61-1 to 61-20 are in no danger of oxidation and corrosion. In addition, the FETs 61-1 to 61-20 are excellent in ON resistance and less dispersion.

In addition, in the solar photovoltaic power generation module 21D, the gate lines are wired in the inside and the power source line becomes necessary because of the provision of the FETs 61-1 to 61-20. However, the solar photovoltaic power generation module 21D adopts a configuration such that the output from the solar photovoltaic power generation module 21D is used as the reference power source, and the FETs 61-1 to 61-20 are operated with the gate terminals thereof being insulated on the control side so that these wirings do not become complicated.

It is noted that, for example, the user manipulates a predetermined inspecting apparatus when he/she inspects the output from the solar photovoltaic power generation module 21D, whereby the switch selection serial data is supplied to the insulating circuit 63. Or, there may be provided a control section for automatically carrying out the inspection by switching the FETs 61-1 to 61-20 in order while both of the output voltage and the output current from the solar photovoltaic power generation module 21D are monitored. In this case, the switch selection serial data may be supplied from the control section to the insulating circuit 63.

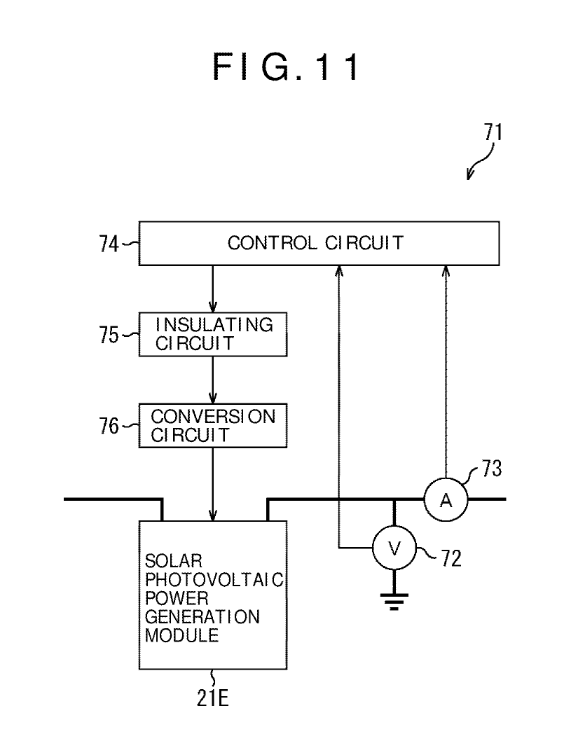

FIG. 11 is a block diagram showing an example of a configuration of an automatically inspecting system for automatically inspecting a solar photovoltaic power generation module.

As shown in FIG. 11, the automatically inspecting system 71 includes a solar photovoltaic power generation module 21E, a voltage measuring portion 72, a current measuring portion 73, a control circuit 74, an insulating circuit 75, and a conversion circuit 76.

The solar photovoltaic power generation module 21E, for example, similarly to the solar photovoltaic power generation module 21D shown in FIG. 10, includes 20 cells 10-1 to 10-20, the bypass diode 22, and 20 FETs 61-1 to 61-20. That is to say, in the solar photovoltaic power generation module 21E, the cells 10-1 to 10-20 are electrically connected in series with one another, the bypass diode 22 is provided between the cells 10-1 and 10-20, and the FETs 61-1 to 61-20 are provided so as to correspond to the cells 10-1 to 10-20, respectively.

The voltage measuring portion 72 measures a voltage (a potential difference with respect to the ground level) of an electric power outputted from the solar photovoltaic power generation module 21E. Thus, a voltage value is sampled at a predetermined timing by the control circuit 74. The current measuring portion 73 measures a current of the electric power outputted from the solar photovoltaic power generation module 21E. Thus, a current value is sampled at a predetermined timing by the control circuit 74.

The control circuit 74 monitors both of the voltage value measured by the voltage measuring portion 72, and the current value measured by the current measuring portion 73. Also, the control circuit 74 supplies the switch selection serial data in accordance with which the FETs 61-1 to 61-20 included in the solar photovoltaic power generation module 21E are selected in order to the insulating circuit 75.

The insulating circuit 74 insulates the FETs 61-1 to 61-20 in order through the conversion circuit 76 in accordance with the switch selection serial data supplied thereto from the control circuit 74. A signal outputted from the insulating circuit 75 to insulate the FETs 61-1 to 61-20 is a serial signal. The conversion circuit 76 converts the signal into a parallel signal.

As described above, when the FET 61 corresponding to the cell 10 having the defect caused therein is insulated, since the defective cell 10 is bypassed, the current of the electric power outputted from the solar photovoltaic power generation module 21E is increased. Therefore, in the automatically inspecting system 71, the insulating circuit 75 insulates the FETs 61-1 to 61-20 in order while the control circuit 74 measures both of the voltage value and the current value, thereby making it possible to detect the cell having the defect caused therein.

Note that, in the automatically inspecting system 71 shown in FIG. 11, a description has been given with respect to the case where the FET 61 is used as the bypass section for bypassing the cell 10. However, for example, a configuration may also be adopted such that the switch 23 as described with reference to FIG. 3 is used as the bypass section, and the magnetic coil 52 as described with reference to FIG. 9 is controlled by the control circuit 74, thereby controlling the open and close of the bypass switch 23.

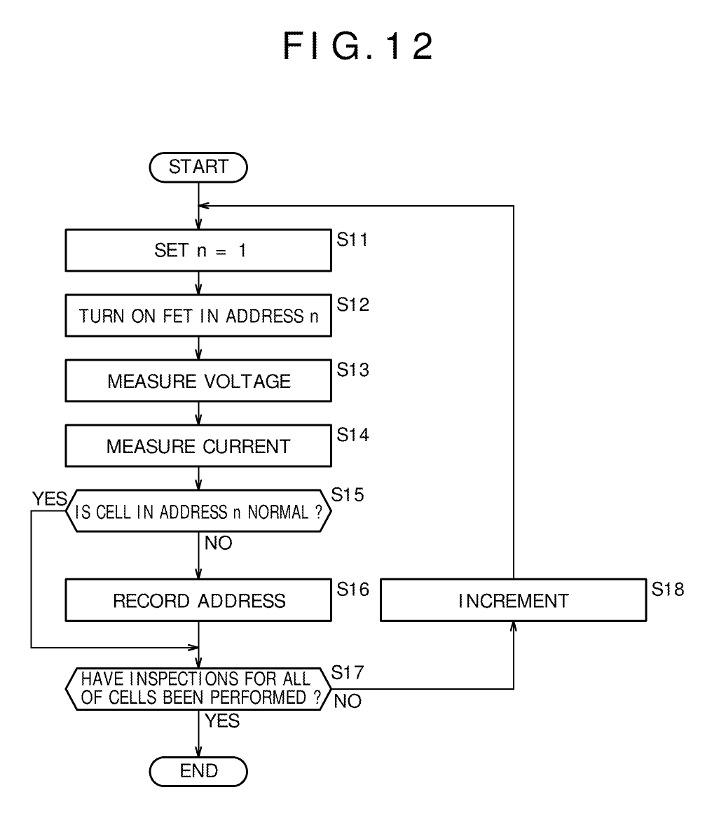

Next, FIG. 12 is a flow chart explaining processing for inspecting the solar photovoltaic power generation module 21E in the automatically inspecting system 71.

In Step S11, the control circuit 74 sets 1 to a variable n specifying an address of the cell 10 becoming an object of the inspection as initial setting for the inspection. Also, the control circuit 74 samples both of the voltage value and the current value in an initial stage (in a state in which the cell 10 is not bypassed), and then the operation proceeds to processing in Step S12.

In Step S12, the control circuit 74 supplies the switch selection serial data representing that the cell 10-n in the address n is selected to the insulating circuit 75. The insulating circuit 75 insulates the FET 61-n through the conversion circuit 76 in accordance with the switch selection serial data, thereby turning ON the FET 61-n. After completion of execution of the processing in Step S12, the operation proceeds to processing in Step S13.

In Step S13, the control circuit 74 samples the voltage value which is measured by the voltage measuring portion 72, and then the operation proceeds to processing in Step S14. In Step S14, the control circuit 74 samples the current value which is measured by the current measuring portion 73.

After completion of execution of the processing in Step S14, the operation proceeds to processing in Step S15. In Step S15, the control circuit 74 determines whether or not the cell 10-n in the address n is normal. For example, when each of the output voltage and the output current from the solar photovoltaic power generation module 21E is reduced by one cell 10 by turning ON the FET 61-n, the control circuit 74 determines that the cell 10-n in the address n is normal. On the other hand, when the output current from the solar photovoltaic power generation module 21E is increased by turning ON the FET 61-n, the control circuit 74 determines that the cell 10-n in the address n is not normal (the defect is caused in the cell 10-n).

When in Step S15, the control circuit 74 determines that the cell 10-n in the address n is normal (YES), the operation skips processing in Step S16 to proceed to processing in Step S17.

On the other hand, when in Step S15, the control circuit 74 determines that the cell 10-n in the address n is not normal (NO), the operation proceeds to processing in Step S16. In Step S16, the control circuit 74 records data on the address n of the cell 10 which is determined not to be normal, that is, data on the current address n for example, in a recording area built therein. Then, the operation proceeds to processing in Step S17.

In Step S17, the control circuit 74 determines whether or not the inspections for all of the cells 10 have been carried out. In the case where the number of cells 10 included in the solar photovoltaic power generation module 21E, for example, is N, when the current variable n is equal to or larger than N, the control circuit 74 determines that the inspections for all of the cells 10 have been carried out (YES). On the other hand, when the current variable n is smaller than N, the control circuit 74 determines that the inspections for all of the cells 10 have not yet been carried out (NO).

When in Step S17, the control circuit 74 determines that the inspections for all of the cells 10 have not yet been carried out (NO), the operation proceeds to processing in Step S18, and the control circuit 74 increments the variable n (n=n+1). Then, the operation returns back to the processing in Step S12. Then, the same pieces of processing are repetitively executed.

On the other hand, when in Step S17, the control circuit 74 determines that the inspections for all of the cells 10 have been carried out (YES), the operation is ended.

The control circuit 74 bypasses all of the cells 10 included in the solar photovoltaic power generation module 21E in order in the manner as described above, and determines whether or not the individual cells 10 are each normal. As a result, it is possible to detect the cell which is determined not to be normal, that is, the cell which has the defect caused therein.

A program in accordance with which such an inspection is carried out is recorded in the control circuit 74. Thus, the control circuit 74 can automatically execute a series of processing, and also the control circuit 74 can periodically inspect the solar photovoltaic power generation module 21E. In addition, even when the response speed of the cell 10 is taken into consideration, the inspection can be carried out within one second per one cell 10. For example, a time required to inspect one sheet of solar photovoltaic power generation module 21E composed of 50 cells 10 can be suppressed within one minute. Therefore, even when the inspection for the solar photovoltaic power generation module 21E is carried out every day, a large influence is not exerted on the energy of electric power generated for one day.

In addition, such an inspection is carried out several times for one day, which results in that it is possible to detect the cell 10 which becomes defective, for example, due to blocking-off of the solar irradiation depending on the time zone. In addition, such an inspection is carried out through one year, which results in that it is possible to detect the cell 10 which becomes defective due to blocking-off of the solar irradiation depending on the season. In such a way, information on the cell 10 which becomes defective due to the external environment such as the time zone and the season is accumulated in the control circuit 74. Thus, by referring to the histories of the cells 10, the setting is carried out in such a way that the defective cell 10 is bypassed in the time zone or the season in which the cell 10 becomes defective, thereby making it possible to optimally control the solar photovoltaic power generation module 21E.

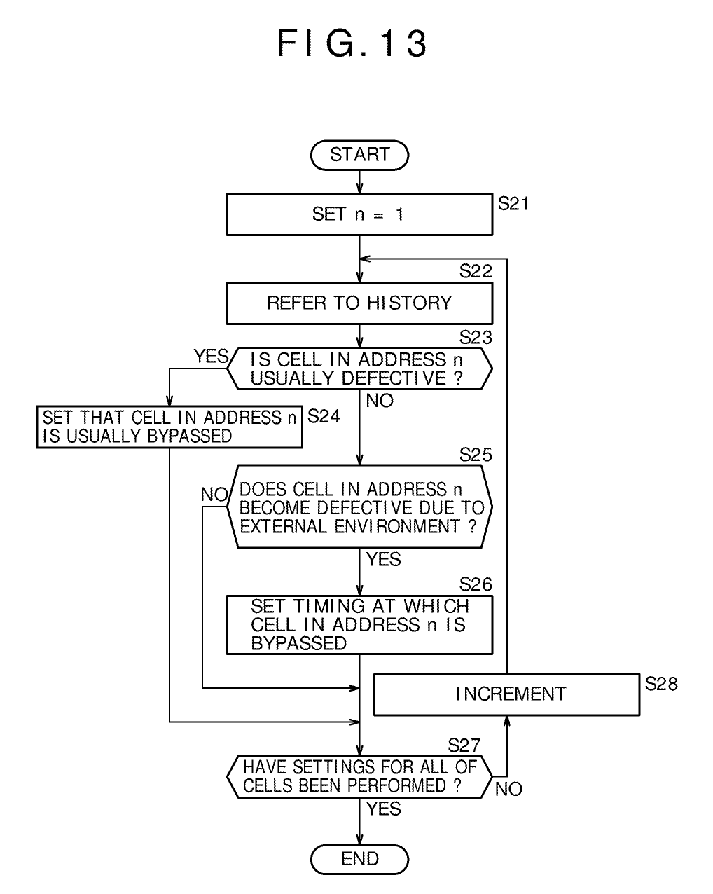

Next, FIG. 13 is a flow chart explaining processing for carrying out the setting for optimally controlling the solar photovoltaic power generation module 21E in the automatically inspecting system 71 shown in FIG. 11.

In Step S21, the control circuit 74 sets 1 to a variable n specifying an address of the cell 10 becoming an object of the inspection as initial setting for the inspection. Then, the operation proceeds to processing in Step S22.

In Step S22, the control circuit 74 refers to the history of the cell 10-n in the address n stored in the storage area built therein.

After completion of execution of the processing in Step S22, the operation proceeds to processing in Step S23. In Step S23, the control circuit 74 determines whether or not the cell 10-n in the address n is always defective in accordance with the history referred in Step S22.

When in Step S23, the control circuit 74 determines that the cell 10-n in the address n is always defective (YES), the operation proceeds to processing in Step S24. In Step S24, the control circuit 74 sets that the cell 10-n in the address n is always bypassed.

On the other hand, when in Step S23, the control circuit 74 determines that the cell 10-n in the address n is not always defective (NO), the operation proceeds to processing in Step S25. In Step S25, the control circuit 74 determines whether or not the cell 10-n in the address n becomes defective due to the external environment in accordance with the history referred in Step S22.

When in Step S25, the control circuit 74 determines that the cell 10-n in the address n becomes defective due to the external environment (YES), the operation proceeds to processing in Step S26. In Step S26, the control circuit 74 sets a timing at which the cell 10-n in the address n is bypassed in accordance with the history referred in Step S22. That is to say, the control circuit 74 carries out the setting in such a way that the cell 10-n is bypassed depending on the time zone and the season in each of which the cell 10-n becomes defective.

When either after completion of execution of the processing in Step S24 or S26, or in Step S25, the control circuit 74 determines that the cell 10-n in the address n does not become defective due to the external environment (the cell 10-n in the address n is always normal) (NO), the operation proceeds to processing in Step S27.

When in Step S27, the control circuit 74 determines whether or not the settings for all of the cells 10 have been carried out. When in Step S27, the control circuit 74 determines that the settings for all of the cells 10 have not yet been carried out (NO), the operation proceeds to processing in Step S28. In Step S28, the control circuit 74 increments the variable n (n=n+1). Then, the operation returns back to the processing in Step S22. Then, the same pieces of processing are repetitively executed. On the other hand, when in Step S27, the control circuit 27 determines that the settings for all of the cells 10 have been carried out (YES), the operation is ended.

As has been described, the control circuit 74 can set that the cell 10 having the defect caused therein is always bypassed, and also can set the timings (the time zone and the season) at each of which the cell 10 which becomes defective due to the external environment, that is, the defective cell 10 is bypassed. As a result, for example, when the condition under which the cell 10 becomes defective is right, the FET 61 is positively turned ON, which results in that it is possible to efficiently prevent the energy of the electric power generated by the solar photovoltaic power generation module 21E from being reduced.

In addition, the processing for carrying out the setting for optimally controlling the solar photovoltaic power generation module 21E is executed at predetermined intervals, which results in that even when the external environment is changed, for example, when the building is newly built in the place near the installation place to change the solar irradiation condition, thereby newly causing the defective cell 10, the setting can be carried out in such a way that the defective cell 10 is suitably bypassed. Thus, it is possible to suitably suppress the reduction of the power generation characteristics of the solar photovoltaic power generation module 21E.

It is noted that when the solar photovoltaic power generation equipment includes plural solar photovoltaic power generation modules 21, the predetermined pieces of processing which have been described with reference to FIGS. 12 and 13 can be executed every solar photovoltaic power generation module 21, and the history for each solar photovoltaic power generation module 21 is recorded in the control circuit 74. That is to say, the control circuit 74 can carry out the optimal control every solar photovoltaic power generation module 21.

It is noted that the predetermined pieces of processing which have been described with reference to the flow charts described above need not to be necessarily executed in time series manner along the order described in the form of the flow chart, and thus include given pieces of processing (such as parallel processing or processing by an object) which are executed either in parallel or individually. In addition, the program either may be a program which is executed by one CPU (central processing unit), or may be a program which is executed in a distributed manner by plural CPUs.

In addition, in this specification, the system means the entire apparatus composed of plural devices (units).

It is noted that the series of processing described above can be executed either by hardware or by software. When the series of processing is executed by the software, a program composing the software is installed from a program recording media either in a computer incorporated in dedicated hardware or, for example, in a general-purpose computer or the like which can carry out various kinds of functions by installing therein various kinds of programs.

In the computer, a program stored in a Read Only Memory (ROM), a program stored in a storage portion composed of a hard disc, a non-volatile memory or the like, and the like are loaded into a Random Access Memory (RAM), and are executed by a CPU. As a result, the series of processing described above is executed.

In addition, these programs can be previously stored in the storage portion, and in addition thereto, can be installed in the computer either through a communication portion composed of a network interface or the like, or through a drive for driving a removable media such as a magnetic disc (including a flexible disc), an optical disc (such as a Compact Disc-Read Only Memory (CD-ROM) or a Digital Versatile Disc (DVD)), a magneto optical disc, or a semiconductor memory.

It is noted that the program which the computer executes either may be a program in accordance with which predetermined pieces of processing are executed in a time series manner along the order described in this specification, or may be a program in accordance with which the predetermined pieces of processing are executed in parallel or at a necessary timing such as when a call is made. In addition, the program either may be a program which is executed by one CPU, or may be a program which is executed in a distributed manner by plural CPUs.

It is noted that the embodiments of the present disclosure are by no means limited to the embodiments described above, and various kinds of changes can be made without departing from the subject matter of the present disclosure.

The present application contains subject matter related to that disclosed in Japanese Priority Patent Application JP 2010-291082 filed in the Japan Patent Office on Dec. 27, 2010, the entire content of which is hereby incorporated by reference.

What is claimed is:

1. A solar photovoltaic power generation module, comprising:
plural cells connected in series with one another, and generating electric powers in correspondence to lights received; and
plural bypass portions bypassing said plural cells, respectively, in accordance with an operation made from an outside.

2. The solar photovoltaic power generation module according to claim 1, wherein the bypass portion is disposed every cell.

3. The solar photovoltaic power generation module according to claim 1, wherein the bypass portion is disposed every at least the two cells so as to be adapted to selectively bypass the adjacent two cells.

4. The solar photovoltaic power generation module according to claim 1, wherein each of said plural bypass portions is composed of a switch having a contact point which is opened and closed by a magnet which is made to come close to the corresponding one of said plural bypass portions from an outside of a panel within which said plural cells are enclosed.

5. The solar photovoltaic power generation module according to claim 4, wherein marks representing positions where the switches are disposed are marked on said panel within which said plural cells are enclosed.

6. The solar photovoltaic power generation module according to claim 1, further comprising:
a voltage measuring portion measuring a voltage of an electric power outputted from said solar photovoltaic power generation module;
a current measuring portion measuring a current of the electric power outputted from said solar photovoltaic power generation module; and
a control portion monitoring the voltage and the current, and controlling bypass made by said plural bypass portions,
wherein said control portion selects said plural cells each becoming an object of an inspection in order, causes the bypass portion corresponding to the cell selected to bypass the cell selected, determines whether or not the cell bypassed is normal in accordance with the voltage and the current, and records the cell which is determined not to be normal.

7. The solar photovoltaic power generation module according to claim 6, wherein said control portion sets a timing at which the cell which is determined not to be normal is bypassed by referring to a history of the cell which is determined not to be normal.

8. An inspecting method for a solar photovoltaic power generation module automatically inspecting system including a solar photovoltaic power generation module having plural cells connected in series with one another, and generating electric powers in correspondence to lights received, and plural bypass portions bypassing said plural cells, respectively, in accordance with an operation made from an outside, a voltage measuring portion measuring a voltage of an electric power outputted from said solar photovoltaic power generation module, a current measuring portion measuring a current of the electric power outputted from said solar photovoltaic power generation module, and a control portion monitoring the voltage and the current, and controlling bypass made by said plural bypass portions, said inspecting method comprising:
successively selecting said plural cells each becoming an object of an inspection;
bypassing the cell selected by the bypass portion corresponding to the cell selected; and
determining whether or not the cell bypassed is normal based on the voltage and the current, and recording the cell which is determined not to be normal.
